(19) United States
(12) Patent Application Publication
(10) Pub. No.: US 2011/0017265 A1
(43) Pub. Date: Jan. 27, 2011

(54) Photovoltaic module with conductive cooling and enhanced reflection

(76) Inventors: James F. Farrell, Toronto (CA); Satyanarayana Rao Peddada, San Jose, CA (US)

Correspondence Address: WOODSIDE IP GROUP, P.O. BOX 61047, PALO ALTO, CA, 94306, US

(21) Appl. No.: 12/583,888

(22) Filed: Aug. 26, 2009

Related U.S. Application Data
(60) Provisional application No. 61/271,776, filed on Jul. 23, 2009.

(51) Int. Cl. H01L 31/052

(52) U.S. Cl. 136/246

(57) ABSTRACT

A thermally conductive material is provided adjacent to or close to the active light-absorbing surface in silicon PV modules made with x-Si or p-Si cells or in thin film PV modules. The material is characterized by high thermal conduction and emissivity as well as high reflectance with respect to the solar spectrum. An exterior portion of the thermally conductive material is wrapped around the rearward facing, shaded surface of the PV module, thereby defining a thermal gradient for conduction of heat from the interior of the PV module to the cooler exterior, where heat is dissipated into the ambient surroundings. The thermally conductive, highly reflective material may be incorporated in or otherwise integrated with a lamination material used to adhere the back sheet to the front sheet of a thin film PV module.

### CROSS REFERENCE TO RELATED APPLICATION

This application claims the benefit of U.S. provisional patent application Ser. No. 61/271,776, filed Jul. 23, 2009.

### BACKGROUND

1. Field of the Invention

The field of the invention generally relates to photovoltaic (PV) modules. In particular, the field of the invention pertains to thin film PV modules and to PV modules constructed from conventional x-Si or p-Si cells, wherein a lamination sheet characterized by a high back reflectance and high thermal conductivity is provided for transporting heat from inside the module to the external ambient surroundings for increased cooling and improved photovoltaic efficiency.

2. Background of Related Art

This invention applies to thin film PV modules and to PV modules constructed from conventional x-Si (single crystal silicon) or p-Si (polysilicon) cells. Such x-Si and p-Si modules do not have back glass, but instead use a PVF back sheet that provides a moisture barrier. A conventional thin film PV module typically consists of a thin film metal reflecting layer or a printed layer of white ink or paint applied over and behind the thin film stack to reflect unabsorbed light back into the thin film stack. The lamination material is usually polyvinyl butyral (PVB), a plastic layer such as DuPont TEDLAR® used between the front and back glass pieces in the laminating process. Such a TEDLAR sheet typically is used in x-Si and p-Si PV modules. Alternatively, ethylene vinyl acetate, also known as EVA, may be used. Such conventional lamination materials are optically clear, and provide no reflectance. In such a conventional thin film PV module, providing reflectance to the back of the thin film stack is complex and expensive, since it requires extra process steps, adds process time, and would require significant capital expenditure for processing equipment.

A further disadvantage in the construction of a conventional thin film PV module is that the lamination materials are not filled and are not thermally conductive. Conventional thin film lamination materials tend to be thermally insulative and disadvantageously cause retention of heat upon prolonged exposure to the sun.

Accordingly, in high intensity sunlight, photovoltaic solar cells become very hot due to the absorption of sunlight and its conversion to heat. Both PV cells and their associated modules exhibit reduced efficiency as their temperature increases. The PV cells which absorb the light and become hot are sandwiched inside the module and are thermally insulated from the outside ambient temperature.

Consequently, what is needed is a process for construction and assembly of thin film PV modules that would enhance the capability of the thin film stack to dissipate heat and thereby increase photovoltaic conversion efficiency in high temperature conditions. It also would be desirable that such construction be provided by a cost effective and straightforward process. Thus, what is also needed is a system and method for constructing a PV module that maximizes kilowatt-hour production while minimizing investment in component cost and installation.

### SUMMARY

In accordance with the foregoing and other objectives, an aspect of the invention improves the efficiency of silicon PV cell modules and thin film PV modules by using a back sheet or lamination material that is characterized by high thermal conduction and emissivity as well as high reflectance with respect to the solar spectrum. That is, such a thermally conductive, highly reflective material forms the back sheet of a silicon cell PV module. The thermally conductive, reflective material also may be incorporated in or otherwise integrated with a lamination material used to adhere the back sheet to the front sheet of a thin film PV module.

An aspect of the invention applies to either a PV module made with a thin film photovoltaic layer, or to PV modules made with x-Si or p-Si cells. In such applications, the thermally conductive material is provided adjacent to or close to the active light-absorbing surface, and provides a path to the exterior of the module for dissipating heat built up around the solar cells directly to the ambient surroundings.

In another aspect of the invention, with respect to thin film PV modules that feature a light absorbing thin film stack, the reflective and thermally conductive lamination material is provided as a sheet adjacent the thin film stack in the interior of the PV module. An exterior portion of the thermally conductive lamination sheet is wrapped around the exterior of the rearward facing surface of the PV module, thereby defining a thermal gradient for conduction of heat from the interior of the PV module to the cooler exterior, where heat is dissipated into the ambient surroundings. The thermally conductive lamination sheet thus defines a path for actively conducting heat from the heated interior of the PV module to the shaded, rearward facing exterior of the PV module and enables the light absorbing portion of the thin film PV module to be cooler in high sunlight conditions.

An aspect of the invention also increases the photocurrent of the active layer of a thin film stack by using a highly reflective material, such as aluminum, as the thermally conductive lamination material used to adhere the back sheet to the front sheet of a PV module. In a thin film application, the front sheet glass of the module contains the photovoltaic thin film stack. Light passing through the thin film stack on the front sheet of the glass generates a photocurrent. Some of the incident light is not absorbed in the thin film stack and passes through the active layer into the lamination material. The lamination material is characterized by highly reflective material such as aluminum having a reflectance value on the order of 95 percent or more for a broad range of solar radiation. Thus, unabsorbed light passing through the thin film stack is reflected back into the active layer, thereby generating additional photocurrent. This aspect of the invention advantageously eliminates the need for a separate paint layer or reflective metal layer to be applied to the thin film stack.

### BRIEF DESCRIPTION OF THE DRAWINGS

The drawings are heuristic for clarity. The foregoing and other features, aspects and advantages of the invention will become better understood with regard to the following description, appended claims and accompanying drawings in which:

FIG. 1 is a side sectional view of a conventional PV module.

FIG. 2 is a side sectional view of a PV module with a highly reflective and thermally conductive foil in accordance with an aspect of the invention.

FIG. 3A is a side sectional view of a thin film PV module with a highly reflective and thermally conductive foil in accordance with an aspect of the invention.

FIG. 3B is a side sectional view of an alternate embodiment of the thin film PV module of FIG. 3A.

### DESCRIPTION OF THE PREFERRED EMBODIMENTS

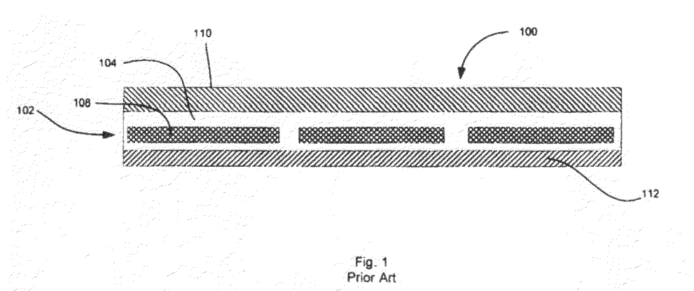

Referring to the drawings, FIG. 1 shows a cross section of a conventional single crystal silicon (x-Si) or polysilicon (p-Si) module 100. Silicon module 100 comprises a plurality of PV cells 102 enclosed in a laminated plastic 104. Such x-Si and p-Si modules do not have back glass, but instead use a PVF back sheet that provides a moisture barrier.

The lamination plastic adjacent the light incident planes 108 of PV cells 102 is transparent. A front cover glass 110 is provided adjacent the transparent lamination plastic for protection against the elements. The backside of the lamination plastic is typically sealed with a PVF film 112 such as Dupont TEDLAR® or other fluoro polymer. Moisture penetration and condensation on the PV cells is responsible for the majority of long term PV module failures. The most vulnerable sites for moisture penetration are at the interface between the cells and encapsulating lamination material 104, and at the interfaces between the glass 110, lamination material 104, and PVF film 112, respectively.

Accordingly, the lamination materials are selected to be highly resistant to penetration or ingress of gases, vapours and liquids. As a result, the materials encapsulating the solar cells develop considerable heat build up within the PV module. In the case of the x-Si and p-Si modules, the thermal path is through the lamination material and front glass, and rear lamination material and the backing sheet, which is usually PVF. Thus, there is only a limited way for the heat to escape. Such heat build up in conventional x-Si and p-Si PV modules reduces efficiency as photovoltaic degradation rates approximately double for each 10 degree C. increase in temperature.

Conventional thin film PV modules likewise suffer degradation in output efficiency due to heat build up, and rely on thermal conduction through the plastic lamination material and the front and back glass in order to cool the higher temperature light absorbing layers. The lamination materials and the front and back glass are not highly thermally conductive, so the cooling of the light absorbing layers is rather poor and inefficient.

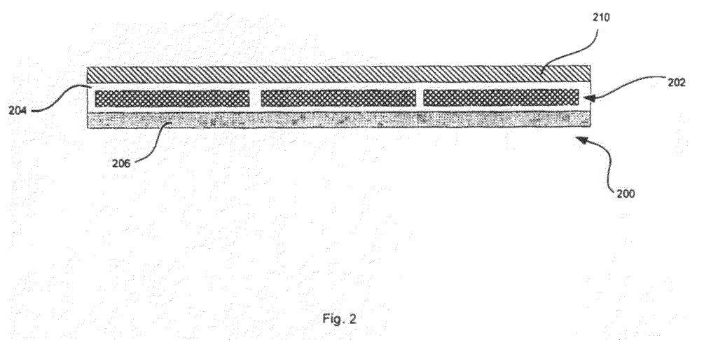

In order to overcome the foregoing disadvantages and deficiencies in conventional PV modules, an aspect of the invention as shown in FIG. 2 provides an improved x-Si or p-Si module 200, comprising a plurality of PV cells 202. The PV cells typically are enclosed in a lamination plastic 204. A transparent protective cover such as a front glass 210 is provided over the light incident side of the plastic 204.

A metal foil or sheet 206 is provided over the back side of the PV module 200. A first surface of metal foil sheet 206 is provided adjacent the plastic sheet 204 and is in close proximity to the solar cells 202. The opposite surface of the foil sheet 206 forms the back or shaded exterior surface of the PV module 200. The metal foil 206 comprises a highly reflective material characterized also by high thermal conductivity and emissivity. Preferably, the metal foil sheet 206 is aluminum or composite thereof, having a thermal conductivity value on the order of 230 W/mK at 25 deg. C. or greater.

In addition, the first surface of foil sheet 206 adjacent the solar cells 202 is treated by well known techniques to have a reflectance value in a range of 90 percent or more and preferably 95 percent or more with respect to solar radiation wavelengths in a range of about 450 to 900 nm. The exterior side of metal foil 206 forms the back or shaded side of the PV module and is open to the ambient surroundings. Thus, due to the high thermal conductivity of the foil sheet, heat developed from the solar cells 202 quickly dissipates through the back side of the foil sheet 206 into the surrounding air, producing a significant cooling effect on the solar cells. The high emissivity of the metal foil 206 is effectively a cooling/heat exchange surface that cools the PV module, resulting in higher photovoltaic efficiency.

In another aspect of the invention, the high reflectance value of the foil sheet with respect to solar radiation reflects unabsorbed sunlight from the space around the PV solar cells back into the lamination material and the front glass where it becomes light guided until it can be directed onto the light incident surface of solar cells 202. Thus, the high diffuse reflectance of metal foil sheet 206 also increases photocurrent generation by the solar cells. The silicon PV cells are much thicker than thin films, so any light incident on the front surface of the silicon PV cell is totally absorbed. However, the light that falls on the area between the cells can be diffusely reflected and will eventually find its way to the front surface of the PV cell and generating additional power.

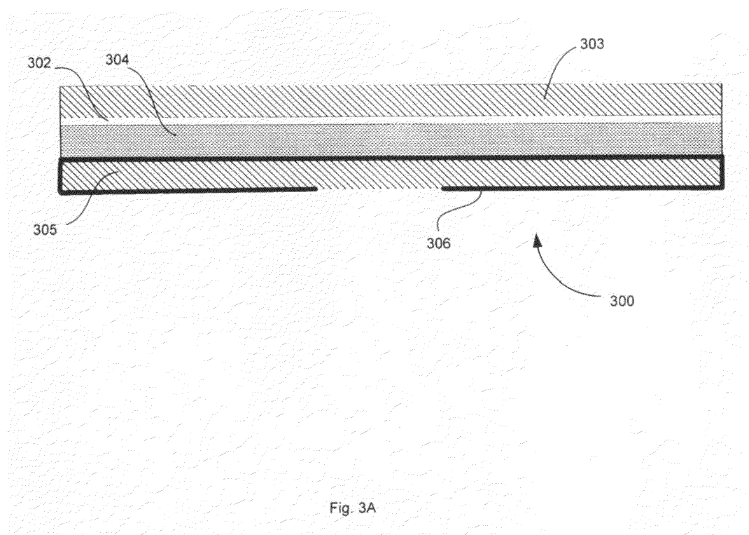

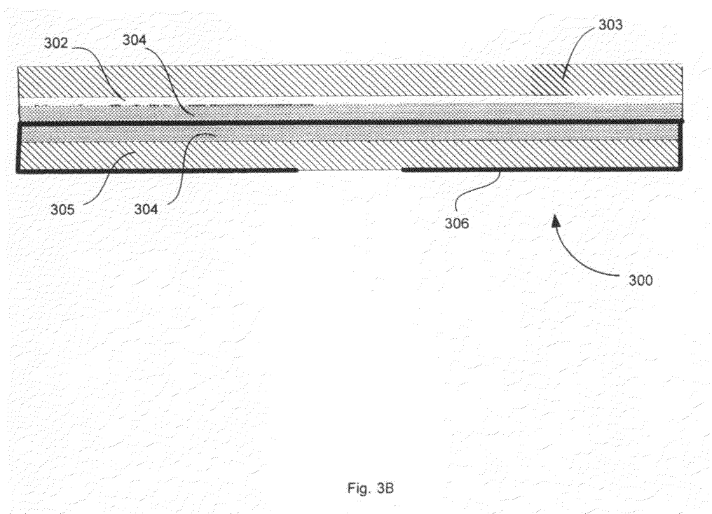

In accordance with another aspect of the invention, FIG. 3 shows an improved thin film PV module 300 incorporating a metal foil that functions as a thermal transport layer for improved cooling and photovoltaic efficiency as well as a reflective layer for reflecting unabsorbed light back into the thin film stack so that more photocurrent is generated.

Referring to FIG. 3A, an improved thin film PV module 300 comprises light absorbing thin film stack 302 having a first or light incident surface protected by a transparent protective cover such as front glass 303 and having a second surface opposite the light incident surface. The thin film stack is provided in accordance with known techniques on an appropriate substrate for lamination to a plastic backing or sheet 304. Metal foil 306 is provided adjacent to the lamination backing 304 for the light-absorbing stack 302. Thus, the interior portion of the metal foil 306 is located in close proximity to the active PV thin film stack where heat is developed from incident solar radiation. Foil 306 further extends to the exterior of the thin film PV module where it is wrapped around the exterior of a back glass sheet 305. Metal foil 306 is adhered to the back glass sheet 305 by means of an adhesive. The metal foil 306 comprises a material, such as aluminum or composite thereof, that is characterized by high thermal conduction and thermal emissivity as well as high reflectivity. The diffuse reflectivity of the foil can be increased substantially by treating the surface of the foil with white paint. Preferably the thermal conductivity value for the foil 306 is on the order of 230 W/mK at 25 deg. C. The preferred range of thickness for the foil is on the order of approximately 0.38 mm. The metal foil is commercially available from several companies, including All Foils, Inc., 16100 Imperial Parkway Cleveland, Ohio 44149 U.S.A.

It will be appreciated that metal foil 306 acts as a thermal transport layer for conducting heat developed by the light absorbing thin film stack away to the cooler exterior, shaded side of the PV module where heat is dissipated. Metal foil 306 defines an elongated thermal path beginning at the interior of the module 300, and extending around the outside of the back glass 305 for effectively conducting heat away from the center of the thin film PV module to the external ambient surroundings on the shaded side of the PV module 300 where heat is dissipated. The cooler exterior surface of the foil 306 on the shaded side of the PV module sets up a significant temperature gradient for enabling heat to be effectively dissipated at the exterior and back sides of the PV module 300. This feature allows the PV module to be cooler in conditions of prolonged exposure to direct sunlight. This aspect of the invention also effectively increases the cooling rate of the PV module by locating a heat sinking material in close proximity to the active PV thin film stack, and providing a thermal path to the ambient air on the outside, for effectively cooling the PV module.

In another aspect of the invention, metal foil 306 also is highly diffusely reflective with respect to the solar spectrum. The foil 306 is characterized by a reflectance value in a range of 90 percent or more and most preferably by a reflectance value of 95 percent or more with respect to solar radiation having wavelengths in a range of about 450 to 900 nm. Foil 306 is thus capable of reflecting unabsorbed light back through the active layers of thin film stack 302. In this aspect of the invention, the metal foil also may be contained in or integrated with a substantially transparent lamination material 304. Lamination material 304 used to adhere the back sheet 305 to the front sheet 303 of the PV module. The back sheet can also be sandwiched between two sheets of lamination material so that the lamination material provides the adhesion to the glass sheets, as in the case of the prior art conventional thin film PV modules. As is well known, the front sheet glass 303 of the module contains the photovoltaic thin film stack.

Light passing through the thin film stack on the front sheet of glass generates a photo current. However, not all of the incident light is absorbed in the thin film stack. Advantageously, the highly reflective quality of the foil material 306 reflects unabsorbed light back into the thin film stack 302 such that additional photocurrent is generated, resulting in improved module efficiency.

Referring to FIG. 3B, an alternate embodiment of a thin film PV module 300 is provided, wherein a metal foil 306 is positioned between two layers or sheets of lamination plastic 304. In this non-limiting example, the front glass has a thickness of approximately 3.2 mm on which is provided a light absorbing thin film stack 302. A layer of lamination plastic 304 approximately 0.38 mm thick is provided adjacent the light absorbing thin film stack 302. A metal foil 306 is positioned between the first lamination layer and a second layer of lamination plastic 304, also having a thickness on the order of approximately 0.38 mm. The second layer of lamination plastic is adhered to the back glass 305 by well known techniques. The metal foil 306 extends around and is adhered to a portion of the exterior surface of the back glass 305.

It will be appreciated that the metal foil 306 for providing a thermally conductive path may be pre-laminated within a single sheet of lamination plastic 304 and provided on a light absorbing stack 302 for adhering a back glass 305 to the module in a single process step The metal foil 306 is characterized by high reflectivity as well as high emissivity. The metal foil 306 is provided in close proximity (0.38 mm) to the light absorbing thin film stack 302, and thereby transports heat away from the inside of module 300 to the outside ambient surroundings. The high reflectivity of the foil material 306 with respect to solar radiation also reflects unabsorbed light back into the thin film stack 302 for additional photocurrent generation and efficiency.

While the invention has been described in connection with what are presently considered to be the most practical and preferred embodiments, it is to be understood that the invention is not limited to the disclosed embodiments, but rather is intended to cover various modifications and equivalent arrangements within the scope of the following claims.

We claim:

1. A PV module, having a light incident surface and a shaded back surface opposite the light incident surface, for converting solar radiation to electrical energy comprising;
a plurality of solar cells forming a light absorbing surface provided on the light incident surface of the PV module for absorbing solar radiation and converting the solar radiation to electrical energy, and forming a second surface opposite the light absorbing surface;
a transparent cover provided on the light-absorbing surface;
a back sheet comprising a thermally conductive material disposed adjacent to the second surface and extending externally to form the shaded back surface of the PV module, such that the thermally conductive material defines a thermal gradient from the solar cells to the shaded back surface for dissipating heat built up around the solar cells to the ambient surroundings.

2. A PV module according to claim 1, wherein the thermally conductive material comprises an aluminum, or composite thereof, metal sheet characterized by a thermal conductivity value on the order of 230 W/mK at 25 deg. C. or greater.

3. A PV module according to claim 1, wherein the solar cells are single crystal silicon, or polycrystalline silicon.

4. An improved thin film PV module incorporating a thermal transport layer for improved cooling and photovoltaic efficiency comprising:
a light absorbing thin film stack having a light-absorbing surface protected by a transparent front cover and having a second surface opposite the light absorbing surface;
a lamination backing provided adjacent the second surface of the thin film stack for laminating the thin film stack to a back sheet having an exterior surface for sealing the light absorbing thin film stack from the elements;
a metal foil provided between the lamination backing and the back sheet, and wrapped around the exterior of the back sheet for conducting heat developed by the light absorbing thin film stack to the exterior surface of the back sheet.

5. A thin film PV module as in claim 4, wherein the metal foil further defines a thermal gradient for conducting heat away from the thin film light absorbing stack to a shaded exterior of the PV module where heat is dissipated.

6. A thin film PV module as in claim 4, wherein the metal foil is characterized by thermal conductivity on the order of 230 W/mK at 25 deg. C. or greater.

7. A thin film PV module as in claim 4, wherein the lamination backing provided adjacent the second surface of the thin film stack is substantially transparent and the metal foil is characterized by a reflectance value having a range of 50 percent or more, and most preferably a range of 95 percent or more with respect to solar radiation wavelengths in a range of about 450 to 900 nm, such that unabsorbed light is reflected back through the light-absorbing thin film stack.

8. An improved thin film PV module incorporating a thermal transport layer for improved cooling and photovoltaic efficiency comprising:
a light-absorbing thin film stack having a light-absorbing surface protected by a transparent front cover and having an interior surface opposite the light-absorbing surface;
a lamination backing provided adjacent the interior surface of the thin film stack for laminating the thin film stack to a back sheet,
a metal foil, provided interiorly in the lamination backing and wrapped around an exterior surface of the back sheet, defining a thermal path for conducting heat developed by the light-absorbing thin film stack to the ambient surroundings.

9. A method for cooling a PV module, having a light incident surface and a shaded back surface, a plurality of solar cells defining a light absorbing surface disposed on the light incident surface, and forming an interior surface opposite the light incident surface, comprising the steps of:
adhering a thermally conductive material to the interior surface of the solar cells;
extending the thermally conductive material externally around the shaded back surface of the PV module, such that the thermally conductive material provides a thermal path for dissipating heat built up by the solar cells to the ambient surroundings.

10. A method for cooling a thin film PV module having a light incident front sheet, a shaded back surface, a thin film stack including a light absorbing surface provided on the light incident front sheet, and having an interior surface opposite the light-absorbing surface, comprising the steps of:
adhering a thermally conductive material to the interior surface of the thin film stack;
extending the thermally conductive material externally around the shaded back surface of the PV module, such that the thermally conductive material defines a thermal path for dissipating heat built up by the solar cells to the ambient surroundings.

11. A method for providing enhanced cooling and photocurrent generation in a thin film PV module having a light incident front sheet, a shaded back sheet, a thin film stack including a light-absorbing surface provided on the light incident front sheet, and having an interior surface opposite the light absorbing surface, comprising the steps of:
providing a substantially transparent lamination backing adjacent the second surface of the thin film stack for laminating the thin film stack to the back sheet;
providing a metal foil between the lamination backing and the back sheet, the metal foil being characterized by high thermal conductivity and a reflectance value having a range of 50 percent or more, and most preferably a range of 95 percent or more with respect to solar radiation wavelengths in a range of about 450 to 900 nm, such that unabsorbed light is reflected back through the light-absorbing thin film stack; and
wrapping at least a portion of the metal foil around the exterior of the back sheet for conducting heat developed by the light-absorbing thin film stack to the ambient surroundings.
